(19) United States
(12) Patent Application Publication
(10) Pub. No.: US 2005/0039089 A1
(43) Pub. Date: Feb. 17, 2005

(54) System and method for analysis of cache array test data

(76) Inventors: Elias Gedamu, Calgary (CA); Denise Man, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/638,568

(22) Filed: Aug. 11, 2003

(51) Int. Cl. G11C 29/00

(52) U.S. Cl. 714/718

(57) ABSTRACT

One embodiment of a method for analysis of cache array test data comprises retrieving cache array test data corresponding to test results of at least one cache array, analyzing the cache array test data, determining a condition of the cache array based upon the cache array test data, and generating an output report indicating a location the determined cache array on a wafer.

### CROSS REFERENCE TO RELATED APPLICATIONS

This application is related to co-pending U.S. utility application entitled, “SYSTEM AND METHOD FOR ANALYSIS OF CACHE ARRAY TEST DATA,” having Ser. No. ____, filed on the same day as the present application, Aug. 11, 2003, attorney docket no. 200208588-1, which is entirely incorporated herein by reference.

### BACKGROUND

FIG. 1 is a simplified exemplary diagram of a fabricated wafer 100 having a plurality of semiconductor devices 102 occupying regions 104 of the wafer 100. That is, a single semiconductor device 102 can be found in region 106 of the wafer 100. Typically, semiconductor devices 102 in regions 104 are designed as identical units, thereby facilitating mass production of many semiconductor devices 102.

After fabrication of wafer 100, a variety of testing may be done on the wafer 100 to identify semiconductor devices 102 that are defective. Such testing may be of a “non-contact” nature. For example, incident light may be used to identify manufacturing defects such as thin or thick areas indicating out-of-tolerance regions on the wafer 100.

Or, testing may be of a “contact” nature wherein a probe device (not shown) is coupled to one or more semiconductor devices 102 on wafer 100. Probe contacts are in frictional contact with terminals of a tested semiconductor device 102, referred to as a device under test (DUT), so that a variety of electrical signals are applied to the DUT semiconductor device 102. Output signals from the DUT semiconductor device 102 are then analyzed and compared with expected designed output signals. Defective semiconductor devices 102 are identified when the test output signals do not correspond with the expected designed output signals.

Probe devices have been designed to test individual semiconductor devices 102. Other probe devices are designed to simultaneously test many semiconductor devices. For example, functionality of a processing unit may be verified by applying a test signal pattern and comparing the output of the processing unit with expected designed output signals.

After testing of wafer 100, the individual semiconductor devices 102 are separated from each other, referred to as singulation. The resultant individual semiconductor device 102 residing on a portion of the wafer is referred to as a die 110. Dies 110 passing the wafer testing process are then mounted on a substrate and encapsulated with a protective cover. The resultant device is referred to as an integrated circuit (IC) chip 112. It is understood that the IC chip 112 having an encapsulated semiconductor device 102 may have a plurality of discrete subunits 108. For example, an IC chip 112 may include a processing unit and one or more associated cache memories, or may be a single unit, such as a memory device.

Typically, a “burn-in” process is used to identify IC chips 112 that would otherwise likely fail after a short period of use. Burn-in processes may vary, but generally consist of operating the IC chip 112 while the IC chip 112 is heated to temperatures above expected normal operating conditions. In some burn-in processes, further testing may occur. Accordingly, a variety of electrical signals are applied to the IC chip 112. Output signals are then analyzed and compared with expected designed output signals. Defective IC chips 112 are identified when the test output signals do not correspond with the expected designed output signals.

The IC chips 112 may be further tested after completion of the burn-in process. Such testing may be very sophisticated and complex, providing a thorough test to ensure that all subunits 108 of the IC chip 112 are properly functioning. Those IC chips 112 passing final testing are then attached to a circuit board 114 with other devices 116.

Detected output signals may be processed and saved as test output data during the above-described testing wherein electronic input signals are applied to the semiconductor device 102, to the IC chip 112, or to discrete subunits 108. The saved test data may be archived for later analysis.

### SUMMARY

A system and method for analysis of cache array test data are described. One embodiment comprises retrieving cache array test data corresponding to test results of at least one cache array, analyzing the cache array test data, determining a condition of the cache array based upon the cache array test data, and generating an output report indicating a location the determined cache array on a wafer.

Another embodiment comprises test data corresponding to testing of at least one cache array residing on a semiconductor device, the test data indicating at least one defect in a portion of the cache array; a memory with logic configured to analyze the test data to identify the cache array having the defective portion, configured to identify a semiconductor device associated with the identified cache array, and further configured to generate an output report having at least a wafer map indicating a location of the identified semiconductor device; and a processor configured to execute the logic.

### BRIEF DESCRIPTION OF THE DRAWINGS

The components in the drawings are not necessarily to scale relative to each other. Like reference numerals designate corresponding parts throughout the several views.

FIG. 1 is a simplified exemplary diagram of a fabricated wafer having a plurality of semiconductor devices occupying regions of the wafer.

FIG. 2 is a simplified exemplary block diagram of a semiconductor device having a cache memory, a processor and at least one subunit.

FIG. 3 is a simplified exemplary block diagram of a cache array test data analysis system coupled to a cache test device.

FIG. 4 is an illustrative output report prepared by embodiments of the cache array test data analysis system.

FIG. 5 shows a flow chart illustrating a process for an embodiment of the cache array test data analysis system.

FIG. 6 shows a flow chart illustrating a process for another embodiment of the cache array test data analysis system.

### DETAILED DESCRIPTION

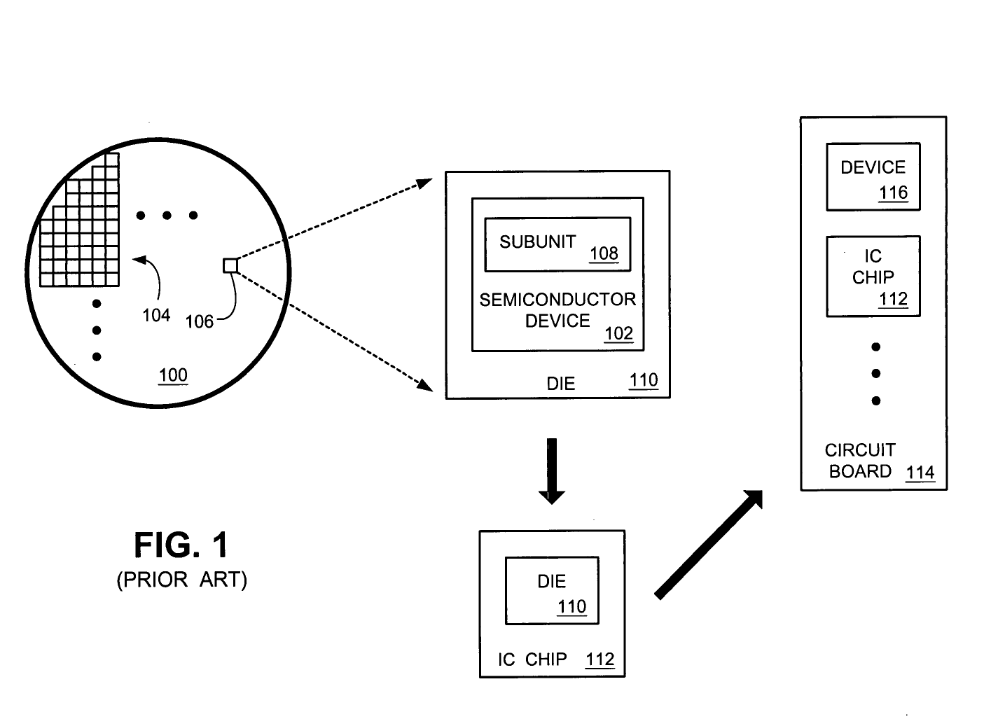

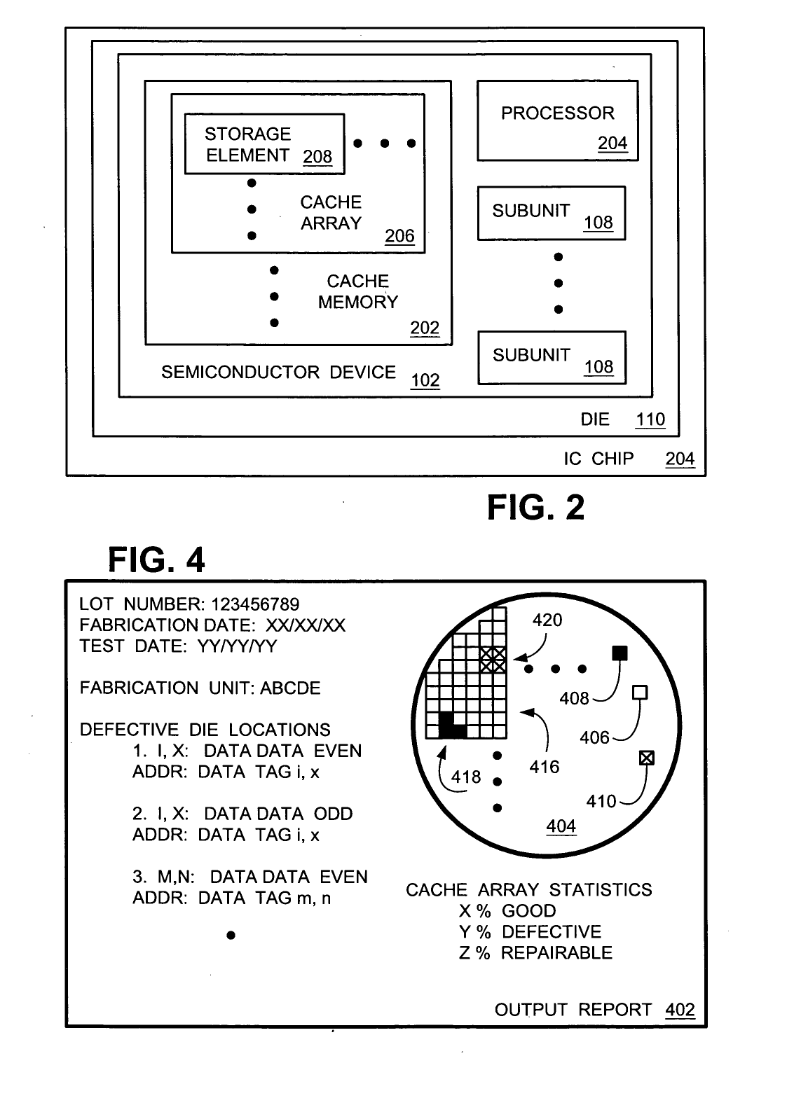

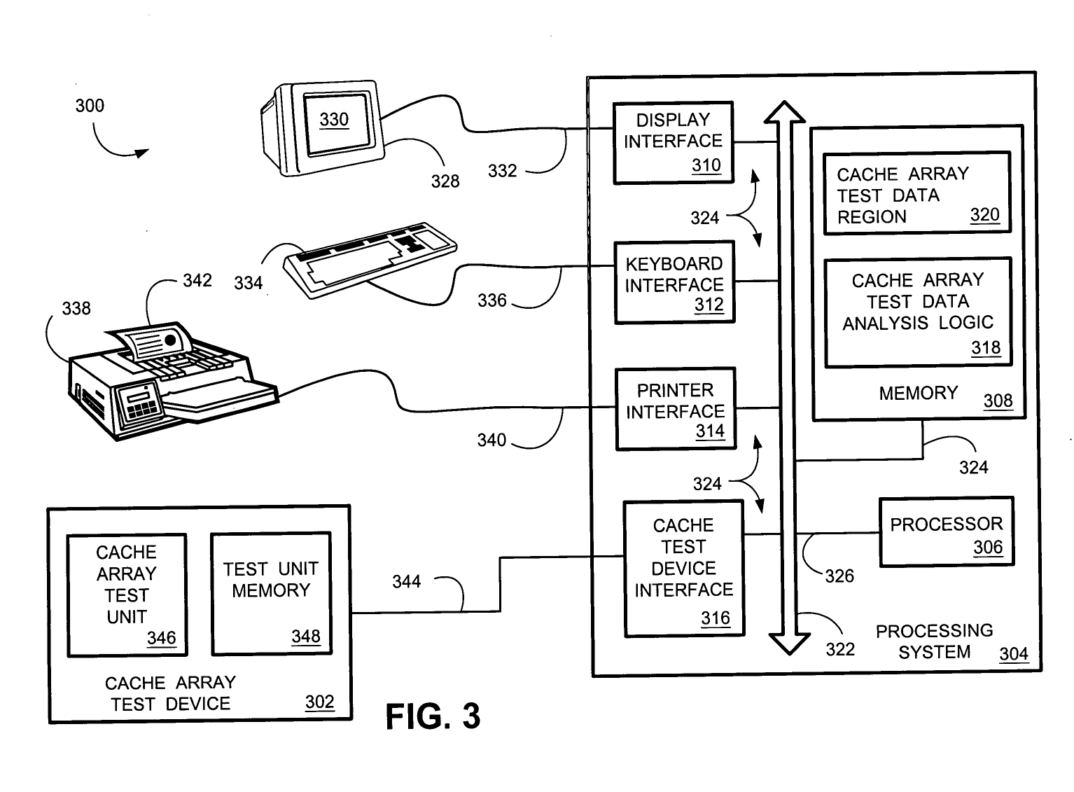

The cache array test data analysts system 300 shown in FIG. 3 analyzes cache array test data from a plurality of cache memories 202 (FIG. 2), and, in one embodiment, identifies corresponding regions of the wafer 100 (FIG. 1) where good, repaired and/or repairable, and defective cache arrays, and their corresponding dies 110, reside.

FIG. 2 is a simplified exemplary block diagram of a semiconductor device 102 having a cache memory 202, a processor 204 and at least one subunit 108. Cache memory 202 comprises at least one cache array 206. A cache array 206 is a region of the cache memory 202. Cache arrays 206 are designed into a cache memory 202 to facilitate programming functions. For example, processor 204, while executing instructions and process various data, uses cache memory 202 as a memory device.

Cache memory 202 is a volatile memory device configured to store data as required by processor 204. Cache arrays 206 improve operational efficiency of processor 204 since the cache arrays 206 have predefined locations on the cache memory 202, thereby enabling the use of pointers or the like by logic executed by processor 204 to identify precisely where data has been stored into cache memory 202. Thus, pointers facilitate quicker storage and/or access of data that is saved into a cache array 206.

A cache memory 202 contains many small transistor-based storage elements 208 that store one bit of data. For example, a group of field effect transistors and other devices may be fabricated onto a semiconductor device 102 such that one bit of data may be stored into the cache memory 202. By fabricating thousands, or even millions, of these small transistor-based storage elements 208 onto a cache memory 202, the cache memory 202 may be configured to store a large amount of data. During fabrication, regions of the cache memory 202 having a relatively large number of small transistor-based storage elements 208 are defined as a cache array 206.

During fabrication of a cache memory 202, the cache memory 202 may be designed to have a plurality of cache arrays 206 to provide redundancy in the event that one or more of the cache arrays 206 are defective. Accordingly, the many small transistor-based storage elements 208 are individually tested to ensure that data can be saved into and retrieved from each portion of a cache array 206. In the event that one or more of the storage elements 208 do not operate properly, the cache array 206 may be reconfigured such that a defective storage element 208 is not used. If a great enough number of the storage elements 208 are defective, the corresponding cache array 206 may be disabled and another properly functioning cache array 206 is substituted in its place. Accordingly, extra cache arrays 206 are fabricated into the cache memory 202 for later use if needed to replace defective cache array.

FIG. 3 is a simplified exemplary block diagram of one embodiment of a cache array test data analysis system 300 coupled to a cache array test device 302. One embodiment of cache array test data analysis system 300 is a processing system 304 comprising a processor 306, a memory 308, display interface 310, keyboard interface 312, printer interface 314 and cache array test device interface 316. Memory 308 may further include a cache test data region 318 and a cache array test data analysis logic 320.

Memory 308, display interface 310, keyboard interface 312, printer interface 314, and cache array test device interface 316 are coupled to communication bus 322 via connections 324. Communication bus 322 is coupled to processor 306 via connection 326, thereby providing connectivity to the above-described components. In alternative embodiments of processing system 304, the above-described components are connectivley coupled to processor 306 in a different manner than illustrated in FIG. 3. For example, one or more of the above-described components may be directly coupled to processor 306 or may be coupled to processor 306 via intermediary components (not shown).

The above-described interfaces 310, 312, 314 and 316 are configured to exchange information from processing system 304 and their respective connected device. For example, display interface 310 is configured to interface between processing system 304 and display device 328 such that a wafer map 404 shown on an output report 402 (FIG. 4) is displayed on display 330.

Keyboard interface 312 is configured to receive operating instructions from a keyboard 334, via connection 336. Printer interface 314 is configured to communicate graphics data from processing system 306 to printer 338, via connection 340, such that a wafer map 404 shown on an output report 402 is printed on printer 338. Cache array test device interface 316 is configured to receive test data corresponding to cache array tests, via connection 344.

For convenience, connections 332, 336, 340 and 344 are illustrated as hardwire connections. Any one of the connections 332, 336, 340 and/or 344 may be implemented with other suitable media, such as infrared, optical, wireless or the like. In other embodiments, the interfaces 310, 312, 314 and 316 are implemented as part of another component residing in processing system 304, such as part of processor 306.

Cache array test device 302 includes a cache array test unit 346 configured to test cache arrays 206 (FIG. 2). Test data resulting from cache array testing is stored in test unit memory 348. Alternatively, the test data may be communicated directly to the cache array test data region 320 of memory 308.

Any suitable cache array test device 302 may be used for testing storage elements 208 (FIG. 2) of a cache array 206. For example, a device configured to perform bit checking and/or bit flipping may be used to test individual storage elements 208 of a cache array 206.

The resultant test data associated with testing cache arrays 206 is very large and complex. The amount of test data is dependent upon the number of storage elements 208 in a tested cache array 206, the number of cache arrays 206 in a tested cache memory 202, and the number of cache memories 202 in a device under test (DUT). The DUT comprises the various devices residing on an individual die.

Furthermore, the amount of test data is dependent upon the number of DUTs tested. For example, all dies from a single wafer 100 (FIG. 1) which are believed to be good may be tested to determine if the cache memories 202 are properly functioning. In that event, many hundreds of cache arrays 206 are tested. If all dies from a plurality of like wafers 100 are tested, even more arrays 206 in the cache memories 202 would be tested. The plurality of like wafers 100 may be from one or more production runs, or may be produced during a specified time period.

Testing of the arrays 206 may be done before singulation of wafer 100 (before dies 110 are cut from the wafer 100). Or, testing of the arrays 206 may be done while the die 110 is on the IC chip 112 (FIG. 1). Or, testing of the arrays 206 may be done while the IC chip 112 in on the circuit board 114. It is understood that testing of arrays 206, and the saving of the resultant test data, may be done at any convenient time during the fabrication process and may be done with any suitable testing device now known or later developed.

As noted above, the saved resultant test data, determined by analyzing the cache array test data and which corresponds to a particular set of tested cache arrays 206, comprises a very large amount of information. This large amount of information is very unwieldy and difficult to process. If manually processed, the information may be difficult to understand and interpret.

The above-described cache array test data indicates performance of individual storage elements 208. However, other associated information may also be included in the cache array test data. For example, associated information may include identification of the cache array 206 of the DUT, and identification of portions of the cache 206 where the storage elements 208 reside. And, identifiers of the DUT and/or location of the DUT may be included in the cache array test data as information. Furthermore, an identifier may be included in the cache array test data which identifies the wafer from which the die came from (or an identifier identifying dies originating from a common wafer), the fabrication date, the fabrication run, the fabrication machine and/or other information of interest.

Thus, embodiments of the cache array test data analysis system 300 are configured to process the test information into information that is readily understandable to a person. Furthermore, the test data processed by some embodiments of the cache array test data analysis system 300 are configured to generate a wafer map 404. The wafer map 404, when displayed and/or printed, indicates the location of dies 110 that have good and/or defective cache arrays 206 on the dies 110 of a common wafer 100. Or, a group of wafers 100 may be further analyzed such that a statistical composite of a wafer map 404 (FIG. 4) is generated. The wafer maps 404 provide an easily understood summarization of the quality of wafer production, and the associated quality of production of semiconductor devices 102 on the wafer 100. That is, a displayed wafer map 404 indicating no (or relatively few) defective dies 110 having defective cache arrays 102 tends to imply an acceptable quality in the fabrication process. On the other hand, a displayed wafer map 404 indicating many (or relatively many) defective dies 110 having defective cache arrays 102 tends to imply an unacceptable quality in the fabrication process.

FIG. 4 is an illustrative output report 402 prepared by embodiments of the cache array test data analysis system 300. Based upon test results identifying acceptable, repaired, and/or defective cache arrays 206 (FIG. 2), a wafer map 404 corresponding to the wafer 100 may be generated. The wafer map 404 in this embodiment symbolically identifies acceptable, repaired, and/or defective dies 110 of a wafer 100 (FIG. 1) based upon the testing of cache arrays 206.

For convenience, acceptable dies are illustrated as white squares 406 on the wafer map 404. Dies having repaired and/or repairable cache arrays 206 are illustrated as black squares 408 on the wafer map 404. Defective dies are illustrated as “x” squares 410 on the wafer map 404. Regions of acceptable dies 416 are illustrated as groups of white squares 406 on the wafer map 404. Similarly, regions of acceptable dies having repaired and/or repairable cache arrays 206 are illustrated as groups of black squares 408, and regions of defective dies 420 are illustrated as groups of “x” squares 410, on the wafer map 404.

It is understood that any suitable symbology and/or nomenclature may be used to identify dies on wafer map 404. For example, a single line through a square may be used to designate a die type (acceptable; repaired or repairable; defective). Or, a colored square may be used to designate a die type. Or, a numeral, letter or other symbol may be used designate a die type. Accordingly, a viewer of the wafer map 404 can readily and quickly identify dies 110 having acceptable, repaired and/or repairable, or defective cache arrays for those dies from a common wafer 100.

Furthermore, cache array test data associated with cache arrays 206 of a plurality of wafers 100 may be analyzed together as a group. Statistical analysis may be further employed to identify regions of the wafer 100 that are defective. As an illustrative example, the wafer map 404 of FIG. 4 may be configured to display only those dies 110 having acceptable, repaired and/or repairable, or defective cache arrays 206 where a predefined number or percentage of dies 110 commonly located exhibit similar performance. To illustrate, assume the user has specified a statistical threshold of 80 percent (80%) for identification of commonly located dies 110 in a group of wafers. If in the group of tested wafers 100, a white square 406 is displayed only when 80% or more of the commonly located dies 110 exhibit acceptable system performance. Furthermore, a black square 408 is displayed only when 80% or more of the commonly located dies 110 exhibit repaired and/or repairable cache array test results. And, an “x” square 410 is displayed only when 80% or more of the commonly located dies 110 are defective. It is understood that any suitable statistically based threshold may be specified.

Output report 402 may further include statistical information of interest in a textual format. For example, the total number of good, repaired and/or repairable, or defective cache arrays may be indicated.

Output report 402 may further include other information of interest in a textual format. For example, the lot number of a group of wafers having tested cache arrays may be indicated. Fabrication and/or testing dates may also be included. Fabrication machine and/or fabrication plant location information may be indicated.

Information indicating die location may be provided in output report 402. For example, the location of a failed die may be specified in Cartesian coordinates or another suitable coordinate system identifying die location on the wafer. Attributes relating to the nature of the tested cache arrays and/or cache memories may also be provided on the output report 402. Non-limiting illustrative examples are shown on the output report 402 of FIG. 4.

Output report 402 is determined from analysis of cache array test data described above. The cache array test data may reside in test unit memory 348 and/or in the cache array test data region of memory 308. When a user desires to view an output report 402, the user causes processor 306 to retrieve and execute cache array test data analysis logic 318 (FIG. 3). Processor 306 retrieves the cache array test data and generates an cache array analysis data file that is used to construct the output report 402.

The constructed cache array analysis data file may be saved for further analysis or reference at a later time. The cache array analysis data file may be saved into a suitable region of memory 308, or saved to another suitable memory.

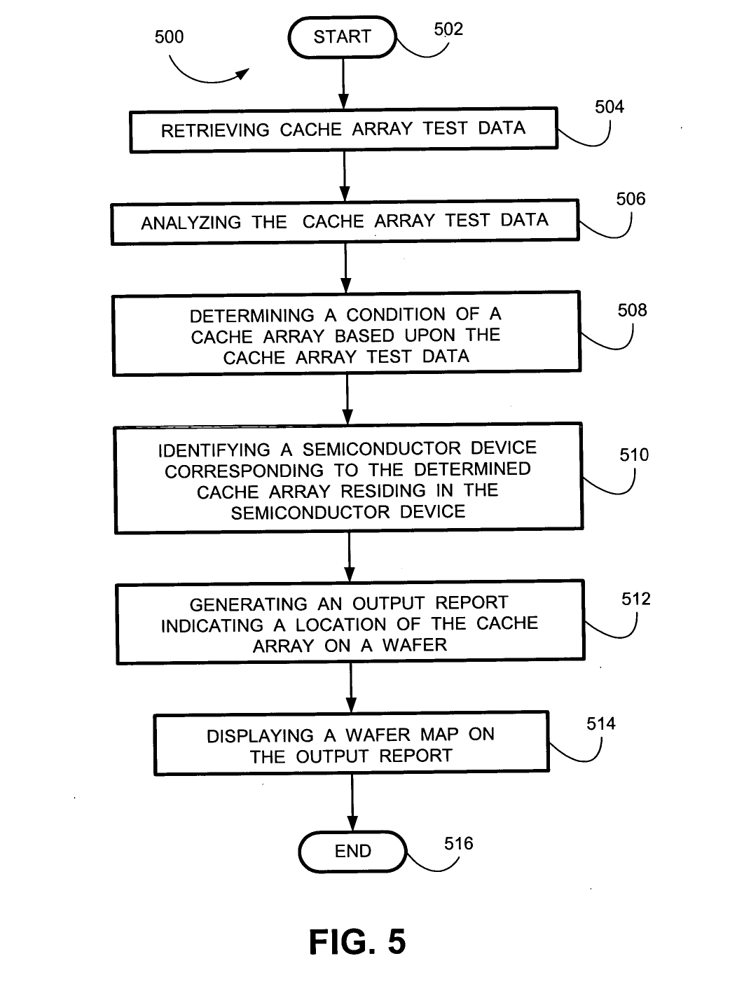

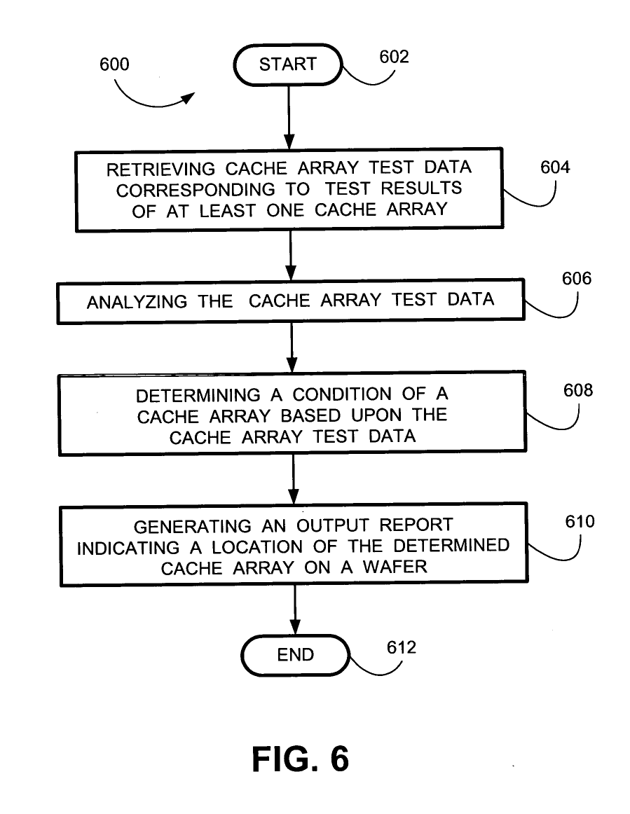

FIG. 5 shows a flow chart 500 illustrating a process for an embodiment of the cache array test data analysis system 300 (FIG. 3). FIG. 6 shows a flow chart 600 illustrating a process for another embodiment of the cache array test data analysis system 300. The flow charts 500 and 600 shows the architecture, functionality, and operation of an embodiment for implementing the cache array test data analysis logic 318 such that test data from a plurality of tested cache arrays 206 (FIG. 2) are analyzed, and corresponding regions of the wafer 100 (FIG. 1) that are good, repaired and/or repairable, and/or defective semiconductor devices 102 residing on a wafer 100 (FIG. 1) can be identified. An alternative embodiment implements the logic of flow charts 500 or 600 with hardware configured as a state machine. In this regard, each block may represent a module, segment or portion of code, which comprises one or more executable instructions for implementing the specified logical function(s). It should also be noted that in some alternative implementations, the functions noted in the blocks may occur out of the order noted in FIG. 5 or 6, or may include additional functions. For example, two blocks shown in succession in FIG. 5 or 6 may in fact be substantially executed concurrently, the blocks may sometimes be executed in the reverse order, or some of the blocks may not be executed in all instances, depending upon the functionality involved, as will be further clarified hereinbelow. All such modifications and variations are intended to be disclosed herein.

The process of flow chart 500 begins at block 502. At block 504, cache array test data corresponding to test results of at least one cache array 206 (FIG. 2) of a semiconductor device 102 is retrieved. In one embodiment the cache array test data is retrieved from a memory. At block 506, the cache array test data is analyzed. At block 508, a condition of the cache array 206 based upon the cache array test data is determined. Depending upon the embodiment, cache arrays 206 that are acceptable, repaired and/or repairable, or defective are identified.

At block 510, a semiconductor device 102 corresponding to the determined cache array 206 is identified. The cache array 206 resides in the semiconductor device 102. At block 512, an output report 402 (FIG. 4) indicating a location of the determined cache array 206 on a wafer 100 (FIG. 1) is generated. At block 514, a wafer map 404 on the output report 402 is displayed, the wafer map 404 indicating the location of the determined cache array 206 on the wafer 100. The process ends at block 516.

The process of flow chart 600 begins at block 602. At block 604, cache array test data corresponding to test results of at least one cache array 206 (FIG. 2) of a semiconductor device 102 is retrieved. At block 606, the cache array test data is analyzed. At block 608, a condition of the cache array 206 based upon the cache array test data is determined. At block 610, an output report 402 (FIG. 4) indicating a location of the determined cache array 206 on a wafer 100 (FIG. 1) is generated. The process ends at block 612.

Embodiments implemented in memory 308 (FIG. 3) may be implemented using any suitable computer-readable medium. In the context of this specification, a “computer-readable medium” can be any means that can store, communicate, propagate, or transport the data associated with, used by or in connection with the instruction execution system, apparatus, and/or device. The computer-readable medium can be, for example, but not limited to, an electronic, magnetic, optical, electromagnetic, infrared, or semiconductor system, apparatus, device, or propagation medium now known or later developed.

For convenience, the embodiment of cache array test data analysis system 300 (FIG. 3) is illustrated as residing in processing system 304. Processing system 304 may be any suitable processing system, such as, but not limited to, a work station, a mainframe computer, a personal computer, a laptop computer or a special purpose processing device. Furthermore, other embodiments of a cache array test data analysis system may be implemented as an integral part of a cache array test device or another testing system that is configured to test cache memory arrays. Such testing devices may also be configured to test other components of a wafer(s), die(s), IC chip(s) and/or circuit board(s).

The output report 402 (FIG. 4) is illustrated as a graphically based report that is viewable on a display or that is printable in hardcopy form. Accordingly, some embodiments of the cache array test data analysis logic 318 may include logic configured to generate graphical output files suitable for display and/or printing. For example, one displayable format is a graphical description file (gdf) file. It is understood that any suitable output format for displaying and/or printing a graphical based output file may be used by embodiments of a cache array test data analysis system 300.

It should be emphasized that the above-described embodiments are merely examples of implementations. Many variations and modifications may be made to the above-described embodiments. All such modifications and variations are intended to be included herein within the scope of the following claims.

1. A system, comprising:
test data corresponding to testing of at least one cache array residing on a semiconductor device, the test data indicating at least one defect in a portion of the cache array;
a memory with logic configured to analyze the test data to identify the cache array having the defective portion, configured to identify a semiconductor device associated with the identified cache array, and further configured to generate an output report having at least a wafer map indicating a location of the identified semiconductor device; and
a processor configured to execute the logic.

2. The system of claim 1, further comprising a cache array test device configured to test the cache array of the semiconductor device.

3. The system of claim 2, wherein the cache array test device further comprises a cache array test unit configured to test a plurality of cache arrays when the semiconductor device resides on a wafer.

4. The system of claim 2, wherein the cache array test device further comprises a cache array test unit configured to test a plurality of cache arrays when the semiconductor device resides on a die.

5. The system of claim 2, wherein the cache array test device further comprises a cache array test unit configured to test a plurality of cache arrays when the semiconductor device resides on an integrated circuit chip.

6. The system of claim 2, wherein the cache array test device further comprises a cache array test unit configured to test a plurality of cache arrays when the semiconductor device resides on a circuit board.

7. A method for analysis of cache array test data, the method comprising:
retrieving cache array test data corresponding to test results of at least one cache array;
analyzing the cache array test data;
determining a condition of the cache array based upon the cache array test data; and
generating an output report indicating a location of the determined cache array on a wafer.

8. The method of claim 7, further comprising identifying a semiconductor device corresponding to the determined cache array, the cache array residing in the semiconductor device.

9. The method of claim 7, wherein determining the condition further comprises determining a defective condition of a semiconductor device when the semiconductor device has at least one defective cache array.

10. The method of claim 7, wherein determining the condition further comprises determining a repairable condition of a semiconductor device when the semiconductor device has at least one repairable cache array.

11. The method of claim 7, wherein determining the condition further comprises determining a repaired condition of a semiconductor device when the semiconductor device has at least one repaired cache array.

12. The method of claim 7, wherein determining the condition further comprises determining a good condition of a semiconductor device when the semiconductor device has good cache arrays.

13. The method of claim 7, further comprising displaying a wafer map on the output report, the wafer map indicating the location of the determined cache array on the wafer.

14. The method of claim 7, further comprising displaying the output report on a display.

15. The method of claim 7, further comprising printing the output report.

16. The method of claim 7, wherein determining further comprises identifying a location of a semiconductor device wherein the cache array resides.

17. The method of claim 7, wherein determining further comprises identifying a location of a die wherein the cache array resides.

18. The method of claim 7, wherein determining further comprises identifying the wafer wherein the cache array resides.

19. The method of claim 7, wherein determining further comprises identifying an integrated circuit chip wherein the cache array resides.

20. The method of claim 7, further comprising:
generating a cache array analysis data file from the analyzed cache array test data, the cache array analysis data file corresponding to the output report; and
saving the cache array analysis data file.

21. A computer-readable medium having a program for analysis of cache array test data, the program comprising logic configured to:
receive cache array test data from a memory, the cache array test data corresponding to test results of the cache array;
analyze the cache array test data;
determine a condition of at least one cache array based upon the cache array test data;
identify a semiconductor device wherein the cache array resides; and
generate an output report indicating a location the identified semiconductor device on a wafer.

22. The computer-readable medium of claim 21, further comprising logic configured to display a wafer map on the output report, the wafer map indicating the location of the identified semiconductor device.

23. The computer-readable medium of claim 21, further comprising logic configured to display a wafer map on the output report, the wafer map indicating a location of a die on the wafer, the die corresponding to the identified semiconductor device.

24. The computer-readable medium of claim 21, further comprising logic configured to:
determine a good condition of the cache array; and
identify the semiconductor device wherein the good cache array resides as a good semiconductor device.

25. The computer-readable medium of claim 21, further comprising logic configured to:
determine a repairable condition of the cache array; and
identify the semiconductor device wherein the repairable cache array resides as a repairable semiconductor device.

26. The computer-readable medium of claim 21, further comprising logic configured to:
determine a repaired condition of the cache array; and
identify the semiconductor device wherein the repaired cache array resides as a repaired semiconductor device.

27. The computer-readable medium of claim 21, further comprising logic configured to:
determine a defective condition of the cache array; and
identify the semiconductor device wherein the defective cache array resides as a defective semiconductor device.

28. The computer-readable medium of claim 21, of further comprising logic configured to identify the wafer wherein the cache array resides.

29. A system for analysis of cache array test data, comprising:
means for analyzing cache array test data received from a memory, the cache array test data corresponding to test results of at least one cache array;
means for determining a condition of the one cache array based upon the cache array test data;
means for identifying a semiconductor device wherein the cache array resides; and
means for generating an output report indicating a location of the determined semiconductor device on a wafer.

30. The system of claim 29, further comprising:
means for determining a good condition of the cache array; and
means for identifying the semiconductor device wherein the good cache array resides as a good semiconductor device.

31. The system of claim 29, further comprising:
means for determining a repairable condition of the cache array; and
means for identifying the semiconductor device wherein the repairable cache array resides as a repairable semiconductor device.

32. The system of claim 29, further comprising:
means for determining a repaired condition of the cache array; and
means for identifying the semiconductor device wherein the repaired cache array resides as a repaired semiconductor device.

33. The system of claim 29, further comprising:
means for determining a defective condition of the cache array; and
means for identifying the semiconductor device wherein the defective cache array resides as a defective semiconductor device.
